(19) United States
(12) Patent Application Publication
(10) Pub. No.: US 2008/0318377 A1
(43) Pub. Date: Dec. 25, 2008

(54) METHOD OF FORMING SELF-ALIGNED GATES AND TRANSISTORS

(76) Inventors: Tzung-Han Lee, Taipei City (TW); Chih-Hao Cheng, Taipei County (TW); Pei-Tzu Lee, Kao-Hsiung City (TW); Te-Yin Chen, Taoyuan County (TW); Chung-Yuan Lee, Tao-Yuan City (TW)

Correspondence Address: NORTH AMERICA INTELLECTUAL PROPERTY CORPORATION, P.O. BOX 506, MERRIFIELD, VA, 22116, US

(21) Appl. No.: 11/964,720

(22) Filed: Dec. 27, 2007

(30) Foreign Application Priority Data
Jun. 23, 2007 (TW) 096122790

(51) Int. Cl. H01L 21/8242

(52) U.S. Cl. 438/243; 257/E21.654

(57) ABSTRACT

Method for fabricating a self-aligned gate of a transistor including: forming a plurality of deep trench capacitors in a substrate, concurrently forming a surface strap and a contact pad on a surface of the substrate, wherein a spacing between the surface strap and the contact pad exposes a portion of an active area, filling the spacing with a dielectric layer, forming a photoresist pattern on the substrate, wherein the photoresist has an opening situated directly above the spacing between the surface strap and the contact pad, etching away the dielectric layer and a portion of a shallow trench isolation region through the opening thereby forming an upwardly protruding fin-typed channel structure, forming a gate dielectric layer on the upwardly protruding fin-typed channel structure, and forming a gate on the gate dielectric layer.

### BACKGROUND OF THE INVENTION

1. Field of the Invention

The present invention relates to a semiconductor manufacturing process, and more particularly to a method of forming self-aligned gates, fin-typed transistors or recessed gate transistors. The present invention can be applied to fabricate high-density trench capacitor DRAMs.

2. Description of the Prior Art

A DRAM (Dynamic random access semiconductor memory) comprises a memory cell array. The memory cells positioned in columns are connected by word lines and the memory cells positioned in rows are connected by bit lines. A DRAM can be operated by using word lines and bit lines to read and program memory cells.

In general, memory cells comprise selection transistors and storage capacitors. The selection transistor is usually a planar FET comprising two diffusion regions separated by a channel, and a gate positioned above the channel. In addition, a word line is connected to one of the diffusion regions and the other diffusion region is connected to the storage capacitor. When a proper bias is applied to the gate through the word line, the selection transistor will be turned on and the current will flow from the diffusion region through the bit line, and then be stored in the storage capacitor.

FinFET is an innovative design, evolved from conventional transistors. Unlike conventional transistors, however, the FinFET is a nonplanar, double-gate transistor built on a substrate. The gate of the FinFET is wrapped around a fin structure. Therefore, the on and off of the FinFET can be controlled by two sides of the gate. The FinFET offers a better circuit control, lower current leakage, lower short channel effect, and higher driving current. In addition, the size of the FinFET is smaller than conventional transistors and the integrity is thereby increased. The number of dies that can be cut from each wafer are increased and the cost is less than a conventional transistor.

The method of forming a FinFET according to a conventional process includes several processes defining the elements on the FinFET, such as etching, deposition, CMP, and ion implantation processes. A plurality of the trench capacitors, an active area, and a gate region, a source region and a drain region positioned between two trench capacitors are defined. In addition, a trench top oxide layer covers each trench capacitor. In order to form a fin-typed gate structure having a long and narrow shape like a fish fin, the conventional process of fabricating the FinFET includes forming a hard mask or a photoresist on the substrate, defining an opening on the hard mask or the photoresist by a photo mask so a portion of the gate region is exposed, determining the position and the dimension of the fin-typed gate structure, and forming a long and narrow fin in the gate region by a following etching process.

The abovementioned method still has many shortcomings. For example, according to the conventional process of making the FinFET, the fin-typed gate structure is defined by a lithography and etching process, but the outline of the fin-typed gate structure is difficult to control in the lithography and etching process. In addition, when the line width is smaller than 70 nm, the critical dimension variation cannot be controlled to be within a certain range, and a short circuit between the FinFETs may occur.

### SUMMARY OF THE INVENTION

To solve the aforesaid problem, a method for fabricating a self-aligned fin-typed gate and a transistor is disclosed.

According to the claimed invention, a method for fabricating a gate with a FinFET structure comprises: deep trench capacitors formed in a substrate; active areas formed in the substrate and connected to the deep trench capacitors in series so as to form multiple columns of a combination of the active areas and the deep trench capacitors; Isolation regions formed in the substrate to isolate two adjacent columns of the combination of the active areas and the deep trench capacitors; forming surface straps on a surface of the substrate to respectively and electrically connect the substrate to the deep trench capacitors and contact pads on the surface of the substrate, wherein a space between every two adjacent surface strap and contact pad exposes a portion of each of the active areas; removing a portion of the isolation regions, so that the exposed portion of each of the active areas is formed as a fin-typed structure; and forming a gate on each of the fin-typed structures.

According to another embodiment of the present invention, a method for fabricating a recessed gate transistor comprises: providing a substrate having a plurality of paralleled isolation regions and deep trench capacitors formed between the isolation regions, wherein an active area is positioned between every two of the deep trench capacitors and the trench isolation regions isolate the active area; forming a surface strap and a contact pad on a top surface of the substrate, wherein the surface strap is electrically connected the substrate to the deep trench capacitor, and a space between the surface strap and the contact pad exposes a portion of the active area; defining a recess in the exposed portion of the active area; and forming a gate in the recess.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1˜4 depict a method for fabricating a FinFET according to a first embodiment of the present invention.

FIGS. 5˜24 depict a method for fabricating a recessed gate and a transistor by a self-aligned process according to a second embodiment of the present invention.

### DETAILED DESCRIPTION

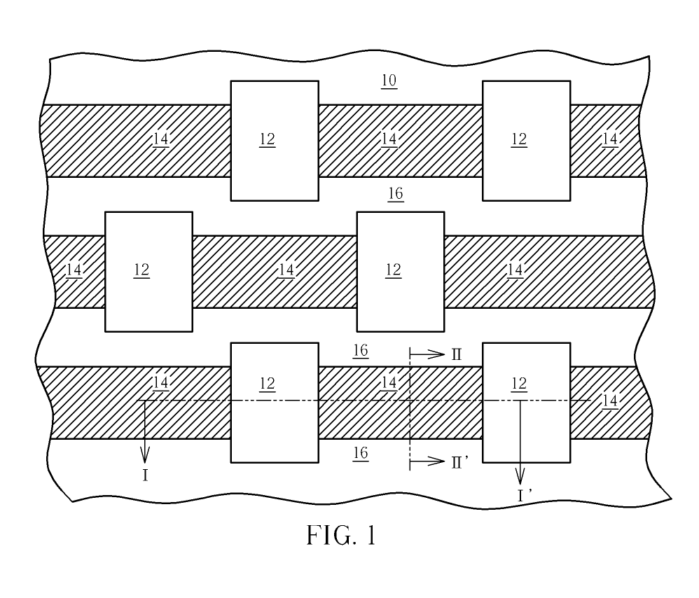

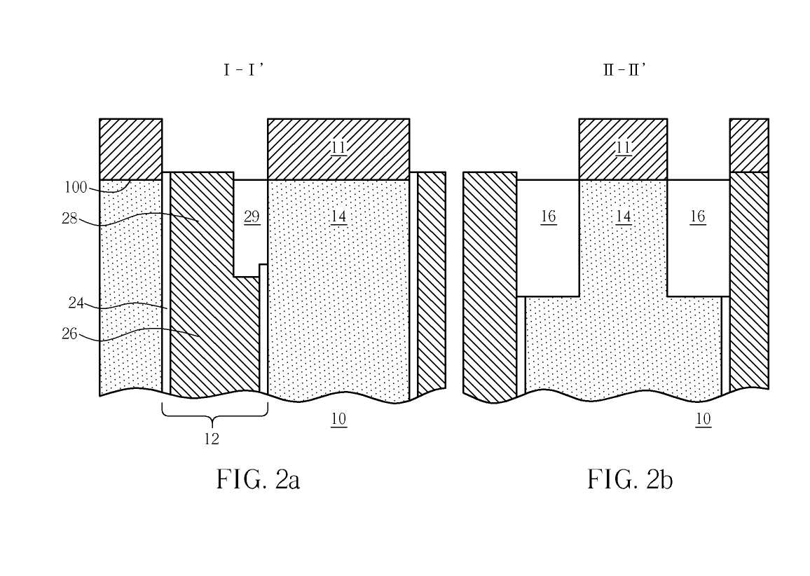

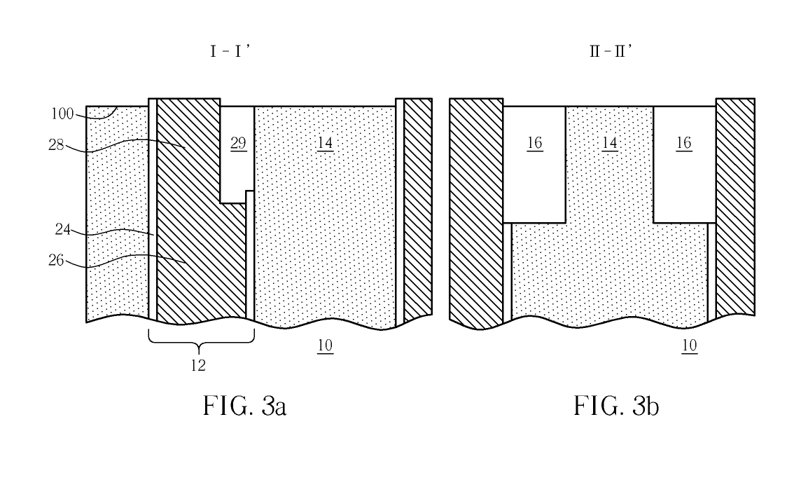

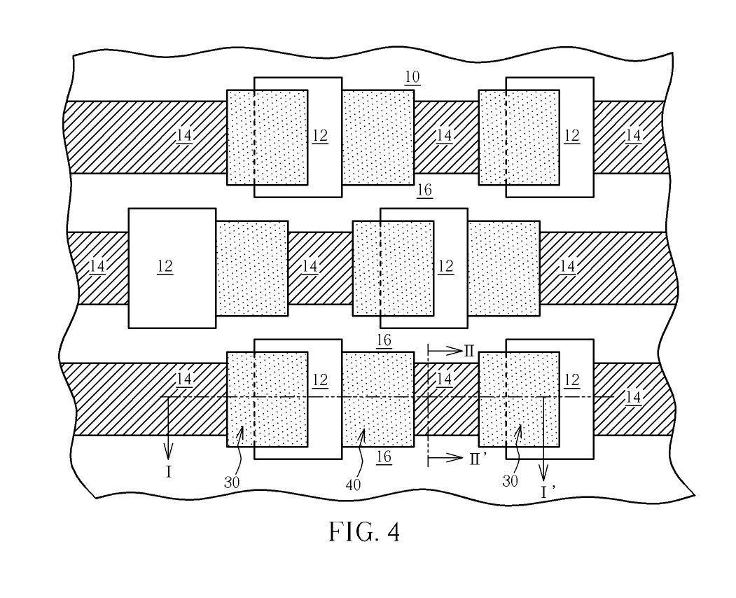

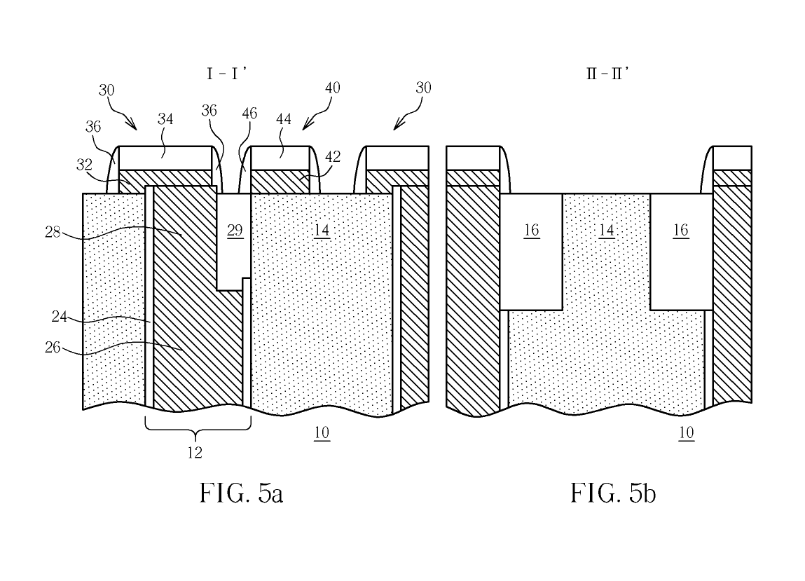

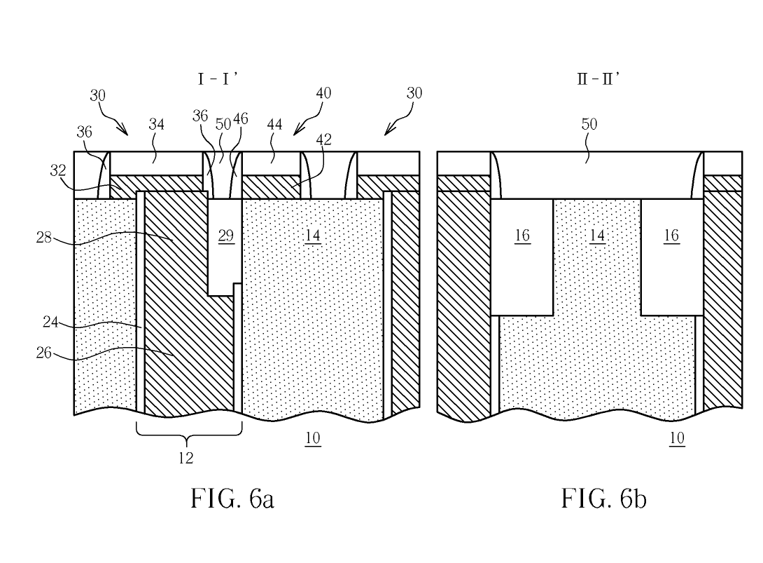

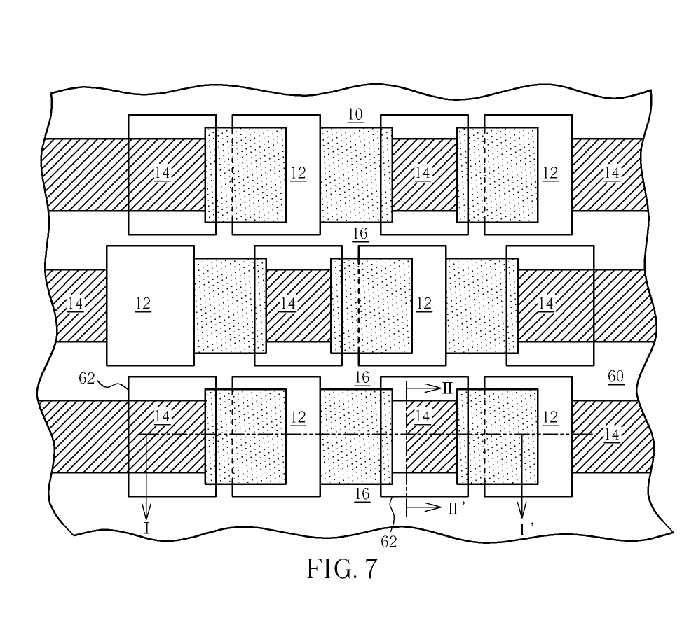

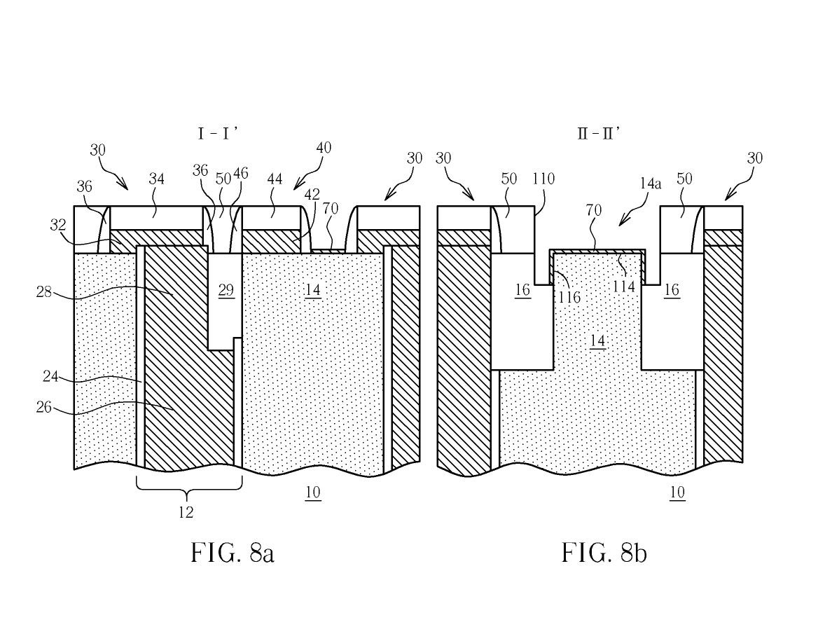

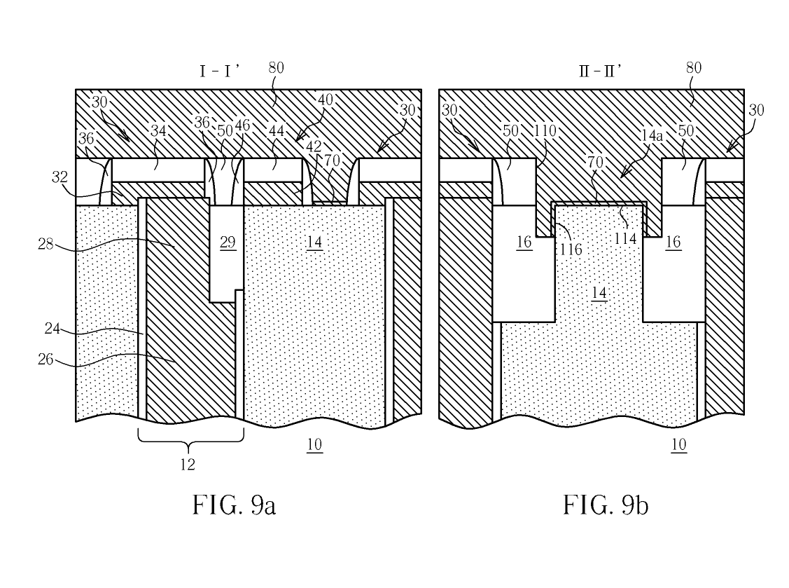

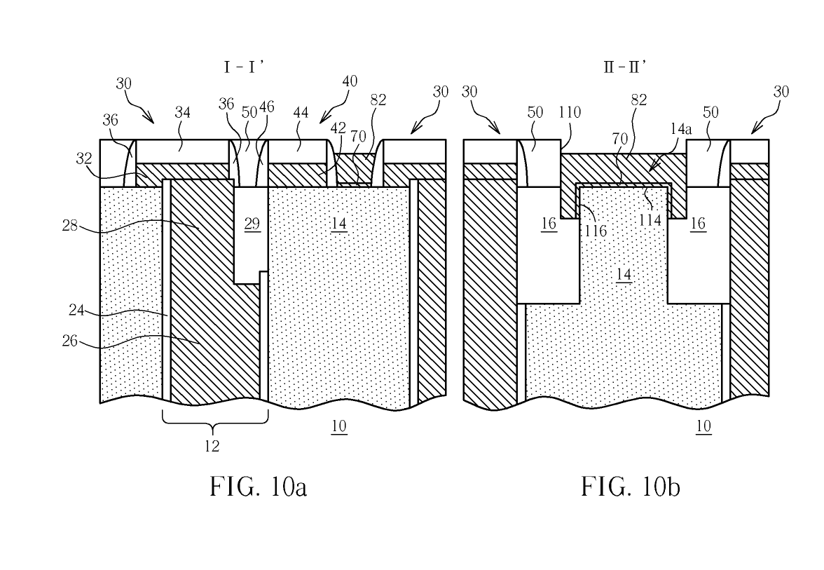

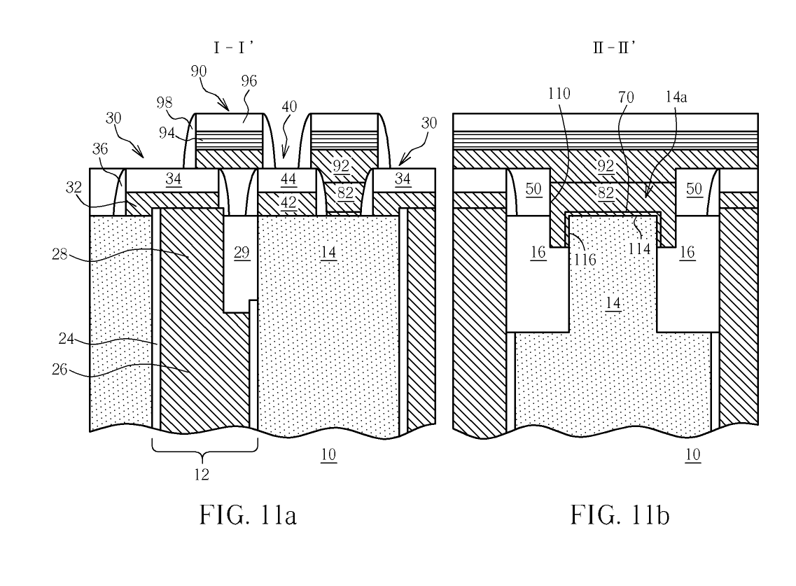

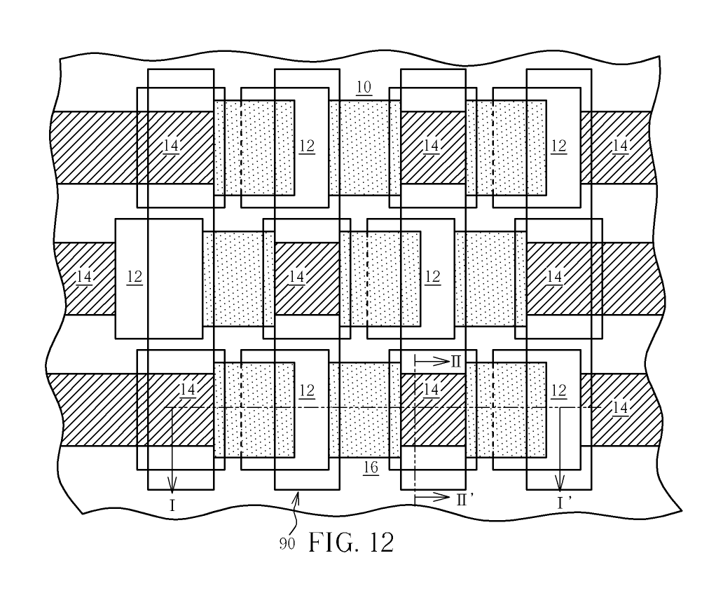

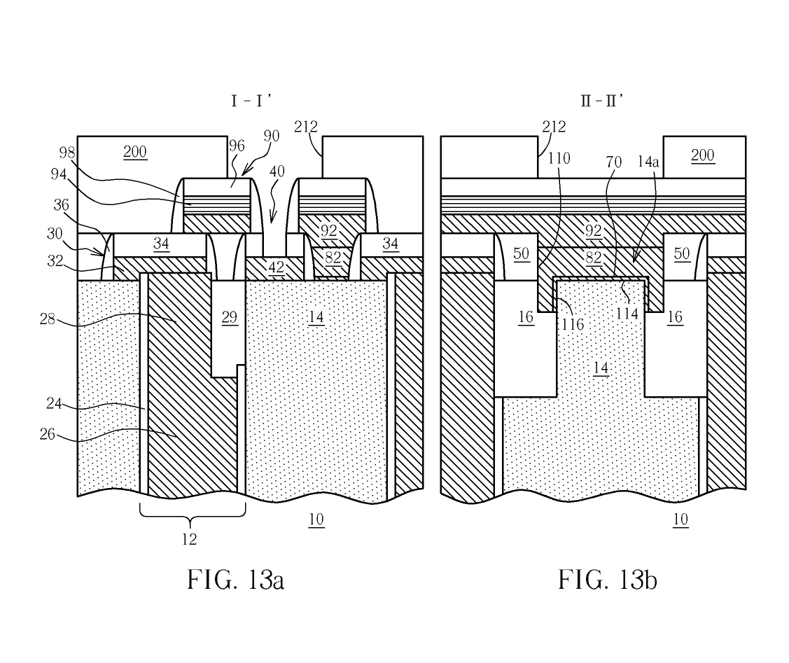

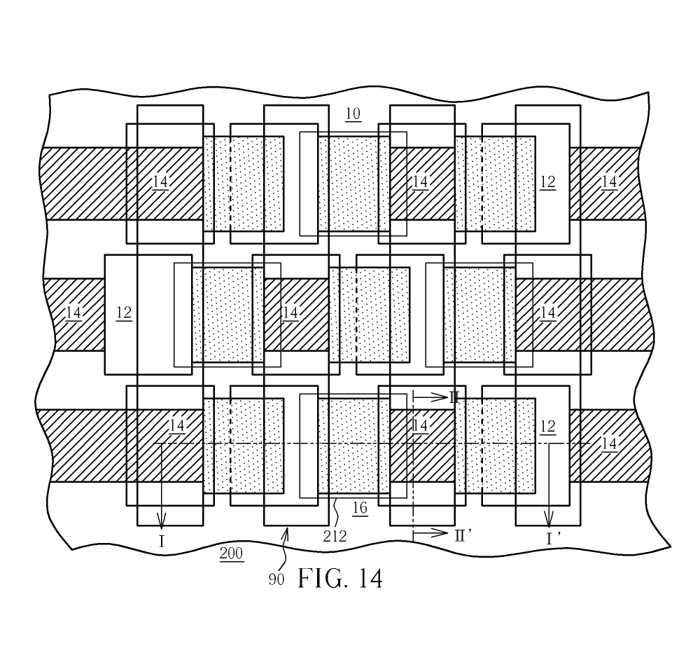

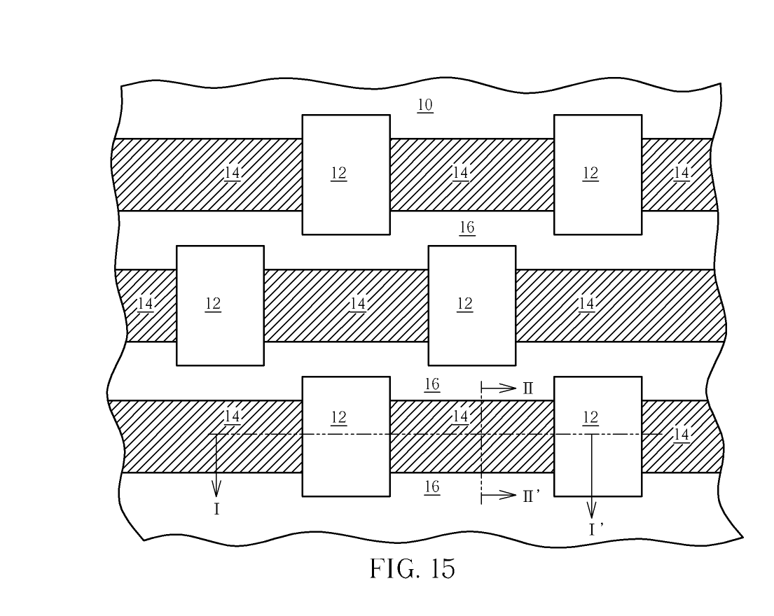

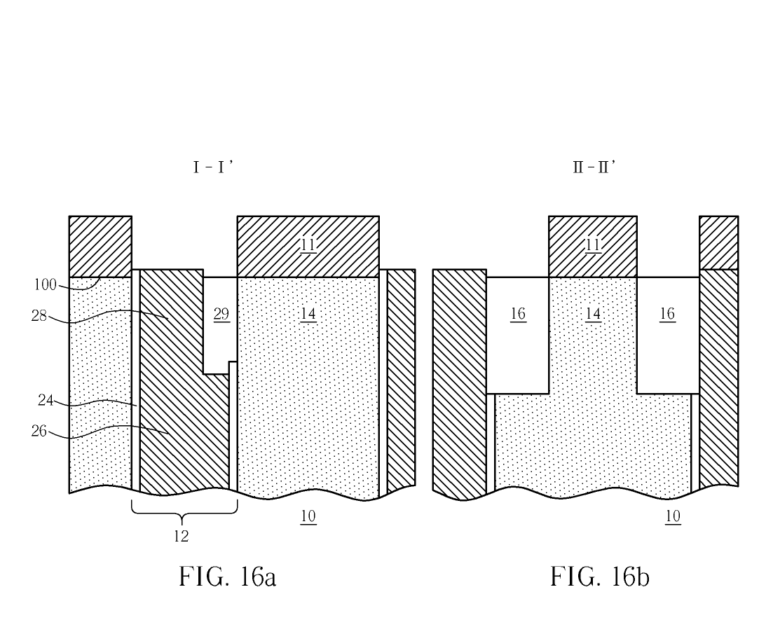

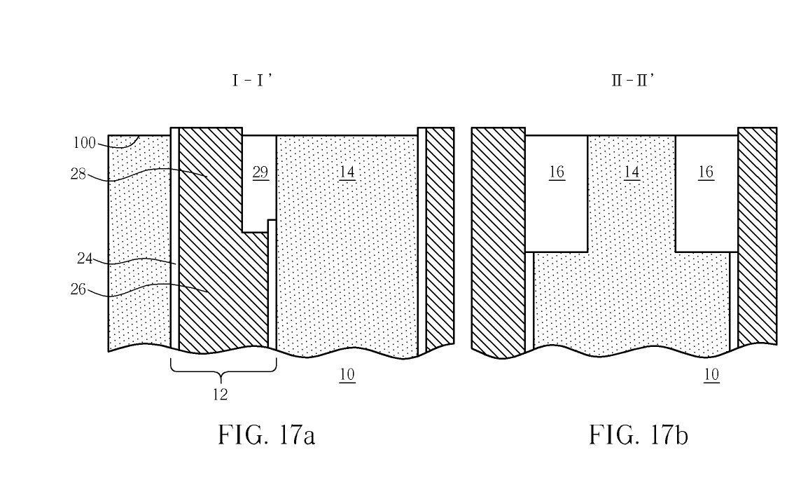

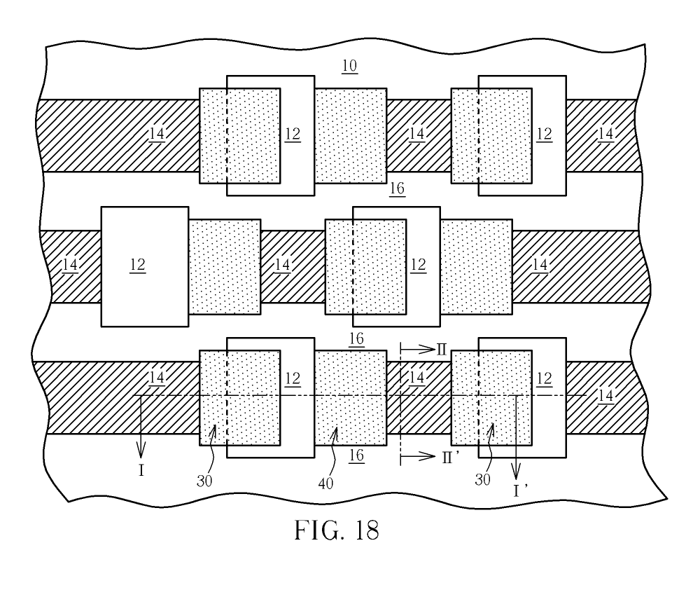

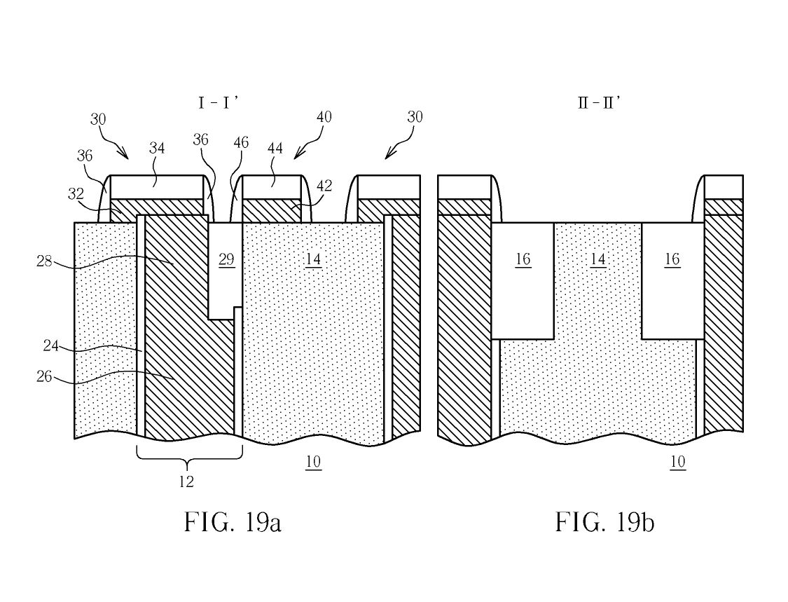

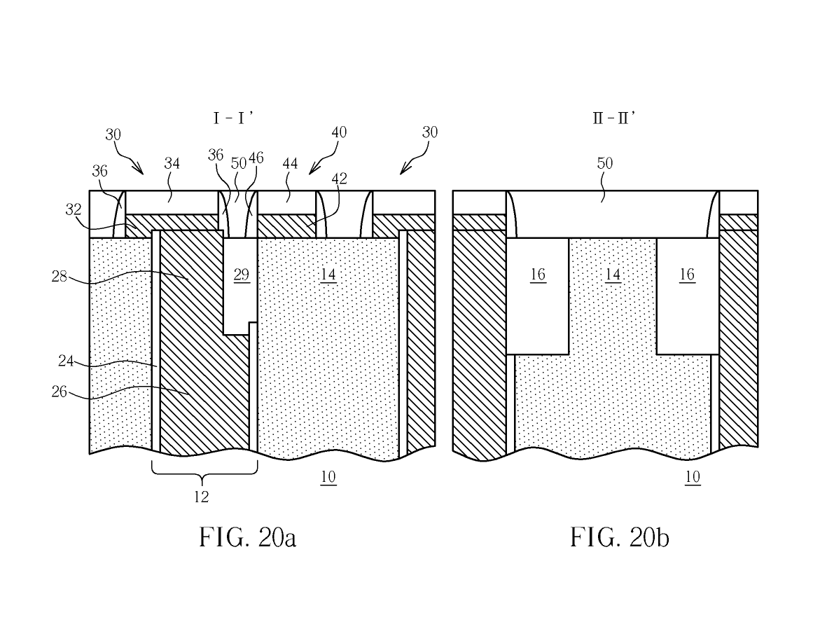

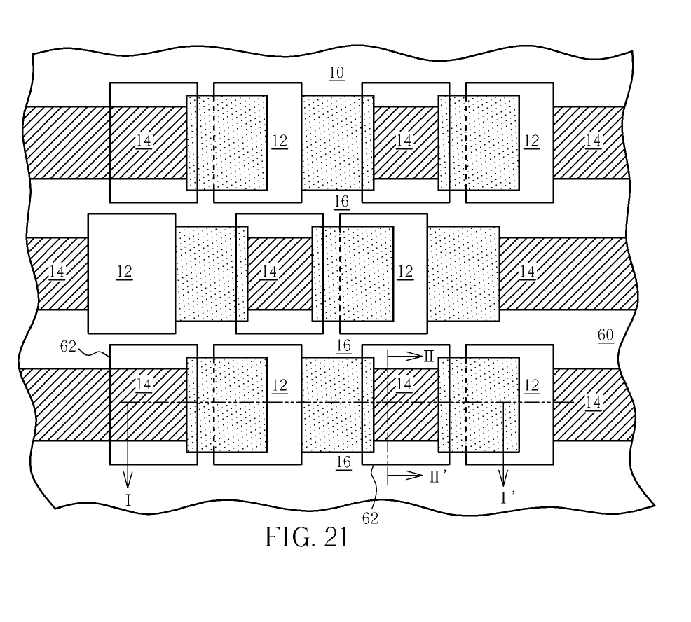

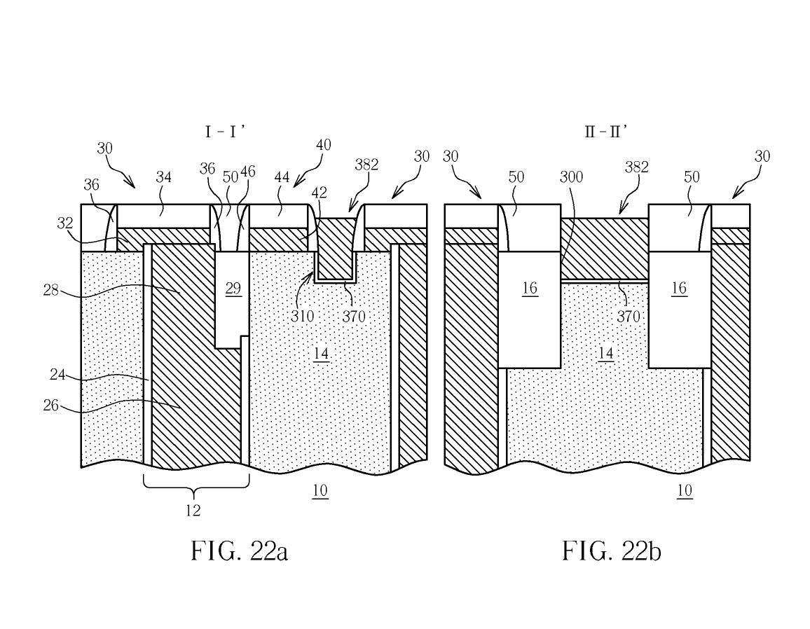

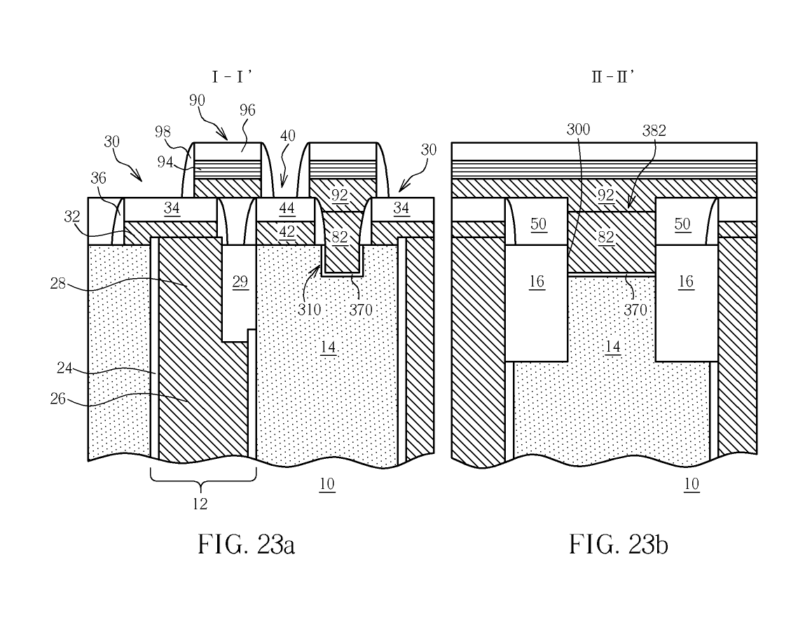

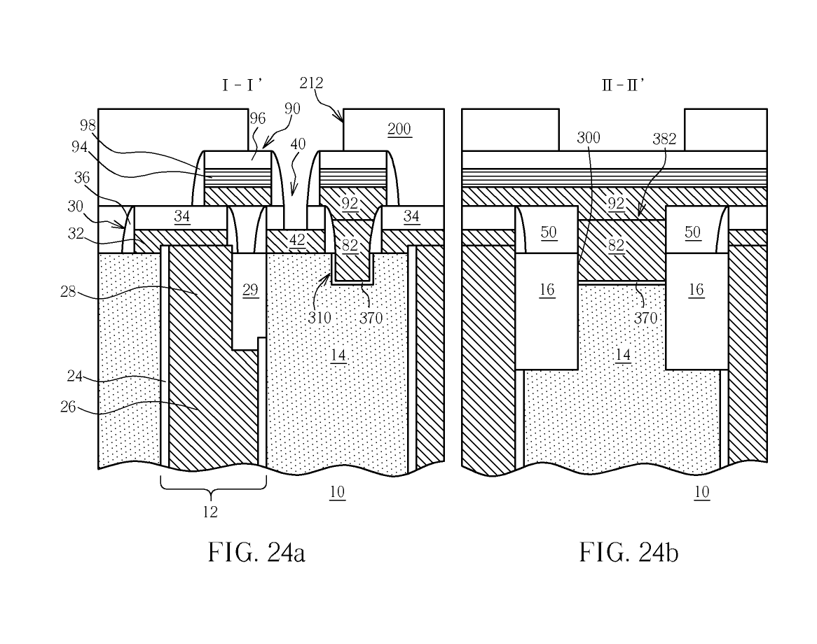

FIG. 1 to FIG. 14 depict a method for fabricating a FinFET according to a first embodiment of the present invention. FIG. 1, FIG. 4, FIG. 7, FIG. 12 and FIG. 14 show a top view of a portion of a memory array. FIG. 2a, FIG. 2b, FIG. 3a, FIG. 3b, FIG. 5a, FIG. 5b, FIG. 6a, FIG. 6b, FIG. 8a, FIG. 8b, FIG. 9a, FIG. 9b, FIG. 10a, FIG. 10b, FIG. 11a, FIG. 11b and FIG. 13a, FIG. 13b depict a sectional view taken along the line I-I′ and II-II′ in FIG. 1. First, as shown in FIG. 1, FIG. 2a, and FIG. 2b, a substrate 10 covered by a pad nitride 11 comprises a plurality of deep trench capacitors 12. The pad nitride 11 is served as an etching hard mask in the deep trench capacitor 12 forming process. An active area 14 is defined between two adjacent deep trench capacitors 12 and a pair of paralleled shallow trench isolation (STI) regions 16. The STI region 16 electrically isolating the active area 14 is filled with silicon oxide.

The deep trench capacitor 12 comprises a sidewall capacitor dielectric layer 24 and a doped polysilicon layer 26, wherein the doped polysilicon layer 26 serves as a top electrode or an inner electrode. In order to simplify the illustration, a buried plate or a bottom electrode is not shown in the figures, and only an upper structure of the deep trench capacitor 12 is shown.

As shown in FIG. 2a and FIG. 2b a single-sided structure 28 is formed on the upper part of the deep trench capacitor 12 by the conventional process, wherein the top surface of the single-sided structure 28 is exposed. In addition, an insulating layer 29 is formed on the deep trench capacitor 12.

One of the features in the present invention is that the single-sided structure 28 and the doped polysilicon layer 26 are completely wrapped by the sidewall capacitor dielectric layer 24 and the insulating layer 29. Therefore, the single-sided structure 28 and the doped polysilicon layer 26 are isolated from the substrate 10.

Another feature of the present invention is that the single-sided structure 28 and the doped polysilicon layer 26 are connected to the other side of the transistor, such as a drain region or a source region through a surface strap formed on the surface 100 of the substrate 10. The method of fabricating the surface strap is illustrated in the following description.

As shown in FIG. 3a and FIG. 3b, the pad nitride 11 is removed from the substrate 10 after the deep trench capacitor 12 is formed. The method of removing the pad nitride 11 may be a wet etching process, such as using a solvent of hot phosphoric acid to immerse the pad nitride. The surface 100 of the substrate 10 will then become flat.

As shown in FIG. 4, FIG. 5a, FIG. 5b a surface strap 30 and a bit line contact pad 40 are formed on the surface 100 of the substrate 10. The surface strap 30 covering a part of the active area 14 is for electrically connecting the active area 14 and the single-sided structure 28 of the deep trench capacitor. The bit line contact pad 40 covers a part of the active area 14, which is a different part to the surface strap 30 covered. The surface strap 30 comprises a polysilicon layer 32, a cap layer 34 and a spacer 36 and the bit line contact pad 40 comprises a polysilicon layer 42, a cap layer 44 and a spacer 46. The surface strap 30 and the contact pad 40 can be formed by depositing a polysilicon layer fully covered the substrate 10, and being defined by the same photo mask. In addition, the cap layer 34 and 44 may be composed of silicon oxynitride, and the spacers 36, 46 may be composed of silicon nitride, but are not limited to this composition.

As shown in FIG. 6a and FIG. 6b, a dielectric layer 50 such as silicon oxide is deposited on the substrate 10 to cover the substrate entirely. The deposition of the dielectric layer 50 can be performed by a chemical vapor deposition (CVD) process. Then, by using the cap layer 34 of surface strap 30 and the cap layer 44 of the contact pad 40 as an etching stop layer, the dielectric layer 50 is polished by a chemical mechanical polishing (CMP) process. Therefore, the dielectric layer 50 after polishing fills the space between the surface strap 30 and the contact pad 40.

As shown in FIG. 7, a photoresist layer 60 is formed on the substrate 10. By using a photolithography, an opening 62 is formed in the photoresist layer 60, wherein the opening 62 overlaps a part of the active area 40 and a part of the STI region 16 positioned at two sides of the active area 14.

As shown in FIG. 8a and FIG. 8b, the dielectric layer 50 and a part of the silicon oxide in the STI region 16 is removed optionally through the opening 62 by an etching process to form a recessed hole 110. After removing a part of silicon oxide in the STI region 16, the substrate 10 is formed as a protruding fin structure 14a in the recess hole on the active areas 14. The protruding fin structure 14a comprises a flat surface 114 and a vertical surface 116. Then, the photoresist layer 60 is removed. Next, a gate dielectric layer 70, such as a silicon dioxide formed by the thermal oxidation process, is formed on the fin structure 14a. In addition, a wet etching process can be performed to etch the protruding fin structure 14a before the gate dielectric layer 70 is formed. The wet etching process is used to round the corner shape of the protruding fin-typed structure.

As shown in FIG. 9a and FIG. 9b, a polysilicon layer 80 is formed on the surface 100 of the substrate 10 by the CVD process. Then, an etching back process is performed to etch the polysilicon layer 80 to expose the cap layer 34, the cap layer 44 and the dielectric layer 50, as shown in FIG. 10a and FIG. 10b. As shown in the sectional view taken along the line II-II″, the protruding fin structure 14a is wrapped by an inverted U-shaped gate structure 82.

As shown in FIG. 11a, FIG. 11b, and FIG. 12, a word line or gate conductor 90 is formed on the substrate 10 to connect the gate structure 82 electrically, wherein the gate conductor comprises a polysilicon layer 92, a metal layer 94, a cap layer 96 and a pair of spacers 98. One of the pair spacers 98 is formed on the cap layer 44 of the contact pad 40. The cap layer 96 may be composed of silicon nitride and the spacer 98 may be composed of silicon nitride as well.

As shown in FIG. 13a, FIG. 13b and FIG. 14, a dielectric layer 200, such as BSG or BPSG is formed on the substrate 10 and a self-aligned contact hole 212 is formed in the dielectric layer 200 by the photolithography process so that a part of the polysilicon layer 42 of the bit line contact pad 40 is exposed. In the following process, the contact hole 212 is filled with conductive matter to serve as a bit line contact plug.

FIG. 15 to FIG. 24 depict a method for fabricating a recessed gate and a transistor by a self-aligned process according to a second embodiment of the present invention. The same elements and regions are given the same numerical numbers for brevity. First, as shown in FIG. 15, FIG. 16a and FIG. 16b, a substrate 10 covered by a pad nitride 11 comprises a plurality of shallow isolation regions (STI) paralleled to each other and plurality of deep trench capacitors 12. The pad nitride 11 is served as an etching hard mask in the deep trench capacitor 12 forming process. An active area 14 is defined between two adjacent deep trench capacitors 12 and two shallow trench isolation regions 16. The STI region 16 electrically isolating the active area 14 is filled with silicon oxide.

The deep trench capacitor 12 comprises a sidewall capacitor dielectric layer 24 and a doped polysilicon layer 26, wherein the doped polysilicon layer 26 serves as a top electrode or an inner electrode. In order to simplify the illustration, a bottom electrode is not shown in the figures, and only an upper structure of the deep trench capacitor 12 is shown.

As shown in FIG. 16a and FIG. 16b, a single-sided structure 28 is formed on the upper part of the deep trench capacitor 12 by the conventional process, wherein the top surface of the single-sided structure 28 is exposed. In addition, an insolating layer 29 is formed on a top portion of the deep trench capacitor 12.

As shown in FIG. 17a and FIG. 17b, the pad nitride 11 is removed from the substrate 10. The method of removing the pad nitride 11 may be a wet etching process, such as using a solvent of hot phosphoric acid to immerse the pad nitride. The surface 100 of the substrate 10 then becomes flat.

As shown in FIG. 18, FIG. 19a and FIG. 19b, a surface strap 30 and a bit line contact pad 40 are formed on the surface 100 of the substrate 10. The surface strap 30 covering a part of the active area 14 is for electrically connecting the active area 14 and the single-side structure 28 of the deep trench capacitor. The bit line contact pad 40 covers a part of the active area 14, wherein the surface strap 30 comprises a polysilicon layer 32, a cap layer 34 and a spacer 36 and the contact pad 40 comprises a polysilicon layer 42, a cap layer 44 and a spacer 46. The surface strap 30 and the contact pad 40 can be formed by the same photo mask. In addition, the spacers 36, 46 may be composed of silicon nitride, but are not limited to this composition.

As shown in FIG. 20a and FIG. 20b, a dielectric layer 50 such as silicon oxide is deposited on top of the substrate 10 to cover the substrate entirely. The deposition of the dielectric layer 50 can be performed by a chemical vapor deposition (CVD) process. Then, by using the cap layer 34 of the surface strap 30 and the cap layer 44 of the bit line contact pad 40 as an etch stop layer, the dielectric layer 50 is polished by a chemical mechanical polishing (CMP) process. Therefore, the dielectric layer 50 after polishing fills the space between the surface strap 30 and the contact pad 40.

As shown in FIG. 21, a photoresist layer 60 is formed on the substrate 10. By using a photolithography process, an opening 62 is formed in the photoresist layer 60, wherein the opening 62 overlaps a part of the bit-line contact pad 40 and a part of the STI region 16 positioned at two sides of the active area 14.

As shown in FIG. 22a and FIG. 22b, the dielectric layer 50 and a part of the substrate in the active area 14 is etched optionally through the opening 62 by a self-aligned dry etching process to form a recessed hole 300 and a recessed trench 310.

Then, the photoresist layer 60 is removed. Next, a gate dielectric layer 370 such as a silicon dioxide is formed on the recessed trench 310 by a thermal oxidation process. Then, a polysilicon layer is formed on the surface 100 of the substrate 10 by the CVD process to fill the recessed hole 300. Then, the polysilicon layer is etched back until the cap layer 34 of the surface strap 30, the cap layer 44 of the bit line contact pad 40 and the dielectric layer 50 is exposed, as the polysilicon layer 82 shown in FIG. 23a and FIG. 23b.

As shown in FIG. 23a and FIG. 23b, sequentially forming a polysilicon layer 92, a metal layer 94 and a cap layer 96 on the polysilicon layer 82 by the conventional photolithography process. After that, a gate 90 is formed. A pair of spacers 98 is then formed on the sidewalls of the gate 90. It has to be mentioned here that the pair of spacers 98 are not only formed on the sidewalls of the gate 90 but are over the cap layer 34 and cap layer 44 respectively.

As shown in FIG. 24a and FIG. 24b, a dielectric layer 200 is formed on the substrate 10. Then a photolithography process is performed and meanwhile using the spacers 98 as a hard mask to form a contact hole 212 in the cap layer 44 of the bit-line contact pad 40. The contact hole 212 is exposed the polysilicon layer 42. In the following process, the contact hole 212 is filled with conductive matter to serve as a bit-line contact plug.

Those skilled in the art will readily observe that numerous modifications and alterations of the device and method may be made while retaining the teachings of the invention.

What is claimed is:

1. A method for fabricating a gate with a FinFET structure comprising
deep trench capacitors formed in a substrate;
active areas formed in the substrate and connected to the deep trench capacitors in series so as to form multiple columns of a combination of the active areas and the deep trench capacitors;
Isolation regions formed in the substrate to isolate two adjacent columns of the combination of the active areas and the deep trench capacitors;
forming surface straps on a surface of the substrate to respectively and electrically connect the substrate to the deep trench capacitors and contact pads on the surface of the substrate, wherein a space between every two adjacent surface strap and the contact pads exposes a portion of each of the active areas;
removing a portion of the isolation regions, so that the exposed portion of each of the active areas is formed as a fin-typed structure; and
forming a gate on each of the fin-typed structures.

2. The gate with a FinFET structure fabricating method as claimed in claim 1, wherein each of the surface straps and the contact pads comprises a polysilicon layer, a cap layer formed on top the polysilicon layer, and a spacer formed on sides of the polysilicon layer.

3. The gate with a FinFET structure fabricating method as claimed in claim 1, wherein each of the deep trench capacitors comprises a sidewall dielectric layer to isolate with the substrate.

4. The gate with a FinFET structure fabricating method as claimed in claim 2, wherein the surface straps and the contact pads are formed concurrently.

5. The gate with a FinFET structure fabricating method as claimed in claim 2, wherein the gate comprises a pair of spacers and one of the spacers is in contact with the cap layer of the contact pad.

6. The gate with a FinFET structure fabricating method as claimed in claim 5 further comprising using the gate spacers as a hard mask to remove a potion of the cap layer and expose the polysilicon layer of the contact pad.

7. A method for fabricating a transistor, comprising:
providing a substrate having a plurality of paralleled isolation regions and deep trench capacitors formed between the isolation regions, wherein an active area is positioned between every two of the deep trench capacitors and the trench isolation regions isolate the active area;
forming a surface strap and a contact pad on a top surface of the substrate wherein the surface strap is electrically connected the substrate to the deep trench capacitor, and a space between the surface strap and the contact pad exposes a portion of the active area;
defining a recess in the exposed portion of the active area; and
forming a gate in the recess.

8. The transistor forming method as claimed in claim 7, wherein the surface strap and the contact pad individually comprises a conductor on the substrate, a cap layer on the polysilicon layer, and a pair of spacers on two sides of the polysilicon layer.

9. The transistor forming transistor forming method as claimed in claim 8, wherein the surface strap and the contact pad are formed concurrently.

10. The transistor forming method as claimed in claim 8, wherein the recess defining step comprises using one side of the spacers of the surface strap and the contact pad as a hard mask to remove a potion of the substrate in the active area.

11. The transistor forming method as claimed in claim 7, wherein each deep trench capacitor comprises a sidewall dielectric layer to isolate with the substrate.

12. The transistor forming method as claimed in claim 7, wherein the gate comprises a pair of spacers and one of the spacers is in contact with the cap layer of the contact pad.

13. The transistor forming method as claimed in claim 12 further comprising using the gate spacers as a hard mask to remove a potion of the cap layer and expose the polysilicon layer of the contact pad.
